(19) United States
(12) Patent Application Publication
(10) Pub. No.: US 2026/0110728 A1
(43) Pub. Date: Apr. 23, 2026

(54) DEVICE FOR CONTROLLING SOLDERED JOINTS ON A BOARD

(71) Applicant: Tatiana Viktorovna SKVORTSOVA, Moscow (RU)

(72) Inventors: Tatiana Viktorovna SKVORTSOVA, Moscow (RU); Dmitriy Mikhailovich LYALYUK, Moscow (RU)

(21) Appl. No.: 18/950,031

(22) Filed: Nov. 16, 2024

(30) Foreign Application Priority Data
Oct. 18, 2024 (RU) 2024131430

(51) Int. Cl. G01R 31/28; H05K 5/00

(52) U.S. Cl. CPC G01R 31/2812; H05K 5/0069

(57) ABSTRACT

The technical solution relates to the field of control of printed circuit (printed circuit boards) assembly and can be used to control the correctness of the soldered connection on the board, as well as in training an untrained user in soldering. There is a need to provide easy-to-learn soldering kits and for studying soldered connections using various electronic components. A device for controlling the soldered connection on the board is proposed. The technical result achieved with the claimed technical solution, in addition to the implementation of the product and/or the method of its use, is a simplification of the design and ensuring ergonomics and ease of use for an untrained user, such as, for example, but not limited to, a child.

### FIELD OF INVENTION

The present invention relates to the field of printed circuit board (PCB) assembly controlling and can be used to control whether soldered connections on the board are correct, as well as to teach an untrained user how to solder.

### DESCRIPTION OF THE RELATED ART

There are various conventional methods and ways of soldering training, including PCB soldering. For example, but not limited to, there are at least 25 different conventional soldering training kits described in the article “Top 25 Cheap and Simple Kits for Learning Soldering and Electronics Principles” (URL: https://pikabu.ru/story/top 25 deshevyikh i prostyikh naborov dlya obucheniya payke i printsipa rabotyi yelektroniki 10452330) [D1]. At the same time, no conventional soldering training kit includes any means for controlling soldered connections, and therefore any conventional kit has limited applicability when teaching an untrained user and when used by an untrained user in general, such as, for example, but not limited to, a child, who won't be able to understand on their own why their soldered connection is faulty, whereas even a specialist will need time to check each soldered connection for defects, such as, for example, but not limited to, solder skip or short circuit. Furthermore, there are no solutions that make it possible to study how certain components placed on the board affect the generated signals, using an easy-to-learn kit that includes an easy-to-learn meter.

Also, patent document RU2212775C2, published on Sep. 20, 2003 [D2], discloses an installation for electrical inspection of printed circuits with adjustable-position probing needles. In the installation for electrical inspection of printed circuits, known from D2, provision is made for using at least two coplanar boards abutting against one another and carrying plurality of conducting needles which are coupled with means for analyzing electrical parameters across one and other needles. However, the solution of D2 and other similar solutions are too complicated for an untrained user, particularly a child aged 7 or older, and therefore cannot be used for teaching untrained users.

Therefore, there is a need in the field to provide easy-to-learn kits for soldering and learning about soldered connections using various electronic components.

The solution disclosed in D2 can be considered the closest prior art to the claimed invention.

### SUMMARY OF THE INVENTION

Technical problem to be solved by the claimed invention is to provide a product and/or a method and/or an implementation of said product or method that eliminate the drawbacks of the prior art and thus enable easy-to-learn and easy-to-operate kits for soldering and/or learning about soldered connections using various electronic components. Another technical problem to be solved by the claimed invention is to provide a product and/or a method and/or an implementation that expand the available technical means, namely devices for controlling soldered connections on a printed circuit board and/or devices and systems for teaching PCB soldering.

The objective of the claimed invention, in addition to the product and/or method fulfilling their purpose, is to simplify the design and to provide an ergonomic and comfortable operation for an untrained user, such as, for example, but not limited to, a child.

The objective of the present invention is achieved by a device for controlling soldered connections on a printed circuit board, the device comprising at least a housing with a seat for a printed circuit board to be controlled, wherein the seat is equipped with a plurality of spring-loaded contacts adapted to couple to counter contacts on the back of said printed circuit board; the device is also equipped with at least one processor that is coupled to said contacts, so that it is possible to check soldered connections on a controlled printed circuit board for at least one of the following defects: solder skip, short circuit, wrong electronic component rating, wrong electronic component, wrong placement of an electronic component; and with a memory storing a program code, which, when executed by the processor, prompts it to at least check at least one soldered connection with at least one electronic component on a printed circuit board placed on the seat for at least one of the defects.

### BRIEF DESCRIPTION OF THE DRAWINGS

Exemplary embodiments of the present utility model are described in further detail below with references made to the attached drawings, included herein by reference:

FIG. 1 illustrates an exemplary device for controlling soldered connections on a printed circuit board.

FIG. 2 shows an exemplary diagram of a device for controlling soldered connections on a printed circuit board.

FIGS. 3 and 4 show an exemplary diagram of a printed circuit board to be controlled.

FIG. 5 illustrates an exemplary device for generating and/or measuring electrical signals.

FIG. 6 shows an exemplary diagram of a device for generating and/or measuring electrical signals.

FIG. 7 shows an exemplary diagram of a system for controlling soldered connections on a printed circuit board and/or analyzing electrical signals.

### DETAILED DESCRIPTION OF THE PREFERRED EMBODIMENTS

According to a preferred embodiment of the present invention, there is provided a device for controlling soldered connections on a printed circuit board, the device comprising at least a housing with a seat for the printed circuit board to be controlled, wherein the seat is equipped with a plurality of spring-loaded contacts adapted to couple to counter contacts on the back of said printed circuit board; the device is also equipped with at least one processor that is coupled to said contacts, so that it is possible to check soldered connections on the controlled printed circuit board for at least one of the following defects: solder skip, short circuit, wrong electronic component rating, wrong electronic component, wrong placement of an electronic component; and with a memory storing a program code, which, when executed by the processor, prompts it to at least check at least one soldered connection with at least one electronic component on the printed circuit board placed on the seat for at least one of the defects mentioned above.

According to an exemplary embodiment of the present invention, there is provided any of the disclosed devices characterized in that said memory is further adapted to store the results of the check.

According to an exemplary embodiment of the present invention, there is provided any of the disclosed devices characterized in that it is additionally equipped with a transceiver adapted to transmit the stored results to a server of a system for controlling soldered connections on a printed circuit board, wherein said memory additionally contains at least a program code, which, when executed by the processor, prompts it to send the stored results to the server.

According to an exemplary embodiment of the present invention, there is provided any of the disclosed devices, characterized in that it is additionally equipped with an output device adapted to at least present the results of the check.

According to an exemplary embodiment of the present invention, there is provided any of the disclosed devices, characterized in that said memory additionally contains at least a program code, which, when at least one of the defects mentioned above is detected, is executed by the processor, prompting it to generate instructions for a user on how to eliminate the detected defect.

According to an exemplary embodiment of the present invention, there is provided any of the disclosed devices, characterized in that said output device is adapted to present the generated instructions to the user.

According to another preferred embodiment of the present invention, there is provided a method for controlling soldered connections on a printed circuit board, in which a printed circuit board to be controlled, with at least one electronic component placed on it by means of soldering, is placed into a seat of any of the disclosed devices for controlling soldered connections on a printed circuit board, and a processor of said device is used to check a soldered connection for at least one of the defects mentioned above.

According to another preferred embodiment of the present invention, there is provided a kit for controlling soldered connections on a printed circuit board, the kit comprising at least one or more of the disclosed devices for controlling soldered connections on a printed circuit board, one or more printed circuit boards to be controlled, which are at least adapted for placing at least one electronic component thereon by means of soldering, and one or more electronic component designed to be placed on the at least one printed circuit board to be controlled that is part of the kit.

According to another preferred embodiment of the present invention, there is provided a system for controlling soldered connections on a printed circuit board, the system comprising at least one or more of the disclosed devices for controlling soldered connections on a printed circuit board, wherein each of the devices is adapted to store in its memory results of said check and is equipped with a transceiver adapted to transmit said stored results via a data exchange network; and a server that comprises at least one or more processors and a memory that stores at least a program code, which, when executed by the processor, prompts it to at least receive and store in the server's memory said results of a check transmitted by any one of the controlling devices.

According to another preferred embodiment of the present invention, there is provided a machine-readable storage medium that stores a program code, which, when executed by at least one processor of said device for controlling soldered connections on a printed circuit board, prompts it to at least check at least one soldered connection with at least one electronic component on said printed circuit board to be controlled, which is placed into a seat of the device for controlling soldered connections, for at least one of the defects mentioned above.

According to another preferred embodiment of the present invention, there is provided a device for generating and/or measuring electrical signals, the device comprising at least a signal generator unit and an oscilloscope unit, and adapted to be coupled to a protoboard, wherein the protoboard is adapted to be detachably coupled to at least one electronic component; and wherein the signal generator unit is adapted to send signals to an input of the oscilloscope unit and an input of the protoboard with an electronic component coupled to it; and wherein the oscilloscope unit has two channels and presents at least a signal that comes from the signal generator unit directly and a signal that comes from the signal generator unit via the protoboard.

According to another preferred embodiment of the present invention, there is provided a method for measuring signals, wherein at least one electronic component is placed on a protoboard, the protoboard is coupled to a disclosed device for generating and/or measuring electrical signals, a signal is sent to the protoboard's input by means of the device's signal generator unit, and a signal value is obtained by means of the device's oscilloscope unit.

According to another preferred embodiment of the present invention, there is provided a kit for generating and/or measuring electrical signals comprising at least one or more of the disclosed devices for generating and/or measuring electrical signals; one or more protoboards adapted to couple to any of the devices for generating and/or measuring electrical signals; and one or more electronic components adapted to be detachably coupled with a protoboard.

Additional alternative embodiments of the present invention are provided below. This disclosure is in no way limiting to the scope of protection granted by the present patent. Rather, it should be noted that the claimed invention can be implemented in different ways, so as to include different components and conditions, or combinations thereof, which are similar to the components and conditions disclosed herein, in combination with other existing and future technologies.

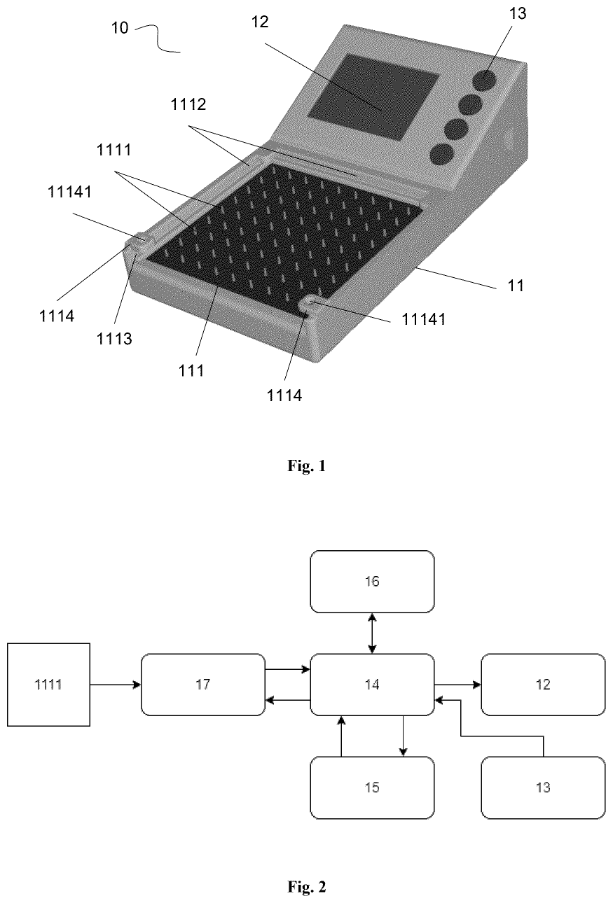

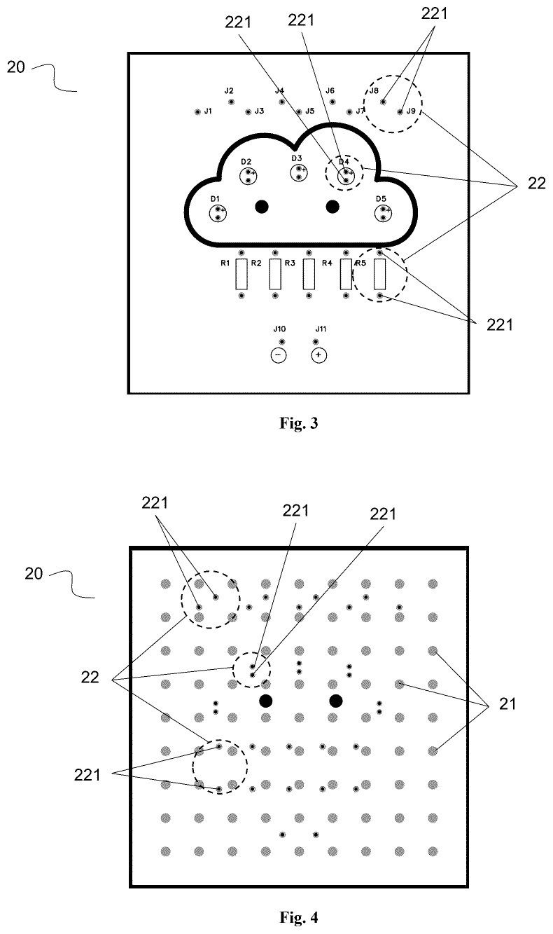

FIG. 1 illustrates an exemplary device 10 for controlling soldered connections on a printed circuit board. FIG. 2 shows an exemplary diagram of device 10 for controlling soldered connections on a printed circuit board. FIGS. 3 and 4 show an exemplary diagram of a printed circuit board to be controlled. According to a preferred embodiment of the present invention, there is provided device 10 for controlling soldered connections on a printed circuit board, the device comprising at least a housing 11 with a seat 111 for the printed circuit board 20 to be controlled, wherein the seat 111 is equipped with a plurality of spring-loaded contacts 1111 (pogo pins 1111) adapted to couple to counter contacts 21 on the back of said printed circuit board 20; device 10 is also equipped with at least one processor 14 that is coupled to said pogo pins 1111, so that it is possible to check soldered connections on the controlled printed circuit board for at least one of the following defects: solder skip, short circuit, wrong electronic component rating, wrong electronic component, wrong placement of an electronic component; wherein, for example, but not limited to, said check is conducted by means of interaction between the processor 14 and a measuring unit 17, which is coupled to the plurality of pogo pins 1111, controlled by the processor 14; and with a memory 15 storing a program code, which, when executed by the processor 14, prompts it to at least check at least one soldered connection with at least one electronic component (not shown in the drawing) on the printed circuit board 20 placed on the seat 111 for at least one of the defects mentioned above. Preferably, but not limited to, the seat 111 is formed by shelves 1112, whereupon said printed circuit board 20 can be at least partially placed, wherein the board is fixed by at least grooves 1113 that are formed by protrusions 1114 and one of the shelves 1112, and wherein the protrusions 1114 can be equipped with holes 11141 for clamp screws (not shown in the drawing). Preferably, but not limited to, printed circuit board 20 is equipped with at least one seat 22 formed by at least two points 221 for placing and soldering an electronic component to the board 20, which are, most typically, metallic holes with conductive pads. Preferably, but not limited to, checks for any of the defects mentioned above are carried out by applying a direct current to the contacts 1111 and then measuring its passing between the points 221. For example, but not limited to, when the board to be controlled has a resistor soldered to it, a voltage drop is measured when the current passes from one point 221 to another, to which the resistor is coupled. For example, but not limited to, this allows at least to determine the class of the soldered component. In addition, preferably, but not limited to, solder skips are detected by applying a direct current as described above and detecting the absence of contact between the conductive contact of the electronic component and the conductive pad of the point 221. In addition, preferably, but not limited to, shirt circuits are detected by measuring a voltage drop between at least two points 221 forming the seat 22 and comparing the measured voltage with the corresponding voltage for the seat 22 stored in memory 15. In addition, preferably, but not limited to, wrong electronic component ratings are detected by measuring the component's rating and comparing it with the given rating that is stored in memory 15 and corresponds to the seat 22, where the corresponding component has been detected. In addition, preferably, but not limited to, wrong electronic components soldered to the seat 22 are detected by determining their highest parameters and comparing them with the values stored in memory 15 that correspond to electronic component classes. In addition, preferably, but not limited to, wrong placement of an electronic component is detected by measuring its ratings between at least two points 221 forming the seat 22 and comparing the measured values with the given values that are stored in memory 15 and correspond to the seat 22, where the corresponding component has been detected. In addition, preferably, but not limited to, alternatively, for certain electronic component classes, such as, for example, transistors, wrong placement is detected by determining the highest parameters of the electronic component and comparing them with the highest parameter values stored in memory 15 that correspond to electronic component classes, and comparing the placement of the soldered electronic component with the placements between two points 221 that are stored in memory 15. At the same time, it should be obvious to a person having ordinary skill in the art that the parameters of the check can be set up, so as to be as suitable as possible for the electronic component soldered to the printed circuit board 20 and/or the set of such electronic components. In addition, preferably, but not limited to, device 10 is also equipped with an output device 12, which is, for example, but not limited to, a display, for example, but not limited to, an LCD display, or a speaker, or the like, In addition, but not limited to, device 10 is also equipped with an input device 13, for example, but not limited to, a button or a touch screen, or a microphone, or the like, adapted to generate an electronic control signal for the processor after the user interacts with said input device 13. In addition, preferably, but not limited to, the results of the check are presented by means of said output device 12. Preferably, but not limited to, said memory 15 is further adapted to store the results of the check. In addition, but not limited to, an electronic component is at least one of the group that includes active electronic components and passive electronic components.

In addition, but not limited to, device 10 may be additionally equipped with a transceiver 16 adapted to transmit the stored results to server 41 of system 40 for controlling soldered connections on a printed circuit board, wherein said memory 15 additionally contains at least a program code, which, when executed by the processor, prompts it to send the stored results to server 41. In addition, but not limited to, said memory 15 may additionally contain at least a program code, which, when at least one of the defects mentioned above is detected, is executed by the processor, prompting it to generate instructions for a user on how to eliminate the detected defect; wherein, for example, but not limited to, said output device 12 may be adapted to present the generated instructions to the user. Alternatively, but not limited to, the generated instructions may be stored in memory 15 and then transmitted to the server 41 of said system 40 by means of transceiver 16, where they will be forwarded, either separately or together with the check results, to automated workplace 42, by interacting with which a controlling user, for example, but not limited to, a teacher, can receive the information on the check results from a plurality of devices 10.

Therefore, but not limited to, there may be provided a method for controlling soldered connections on a printed circuit board, in which a printed circuit board 20 to be controlled, with at least one electronic component placed on it by means of soldering, is placed into a seat 111 of device 10 for controlling soldered connections on a printed circuit board, and a processor 14 of said device 10 is used to check a soldered connection for at least one of the defects mentioned above.

Therefore, but not limited to, there may be provided a kit for controlling soldered connections on a printed circuit board, the kit comprising at least one or more of the disclosed devices 10 for controlling soldered connections on a printed circuit board, one or more printed circuit boards 20 to be controlled, which are at least adapted for placing at least one electronic component thereon by means of soldering, and one or more electronic component designed to be placed on the at least one printed circuit board 20 to be controlled that is part of the kit.

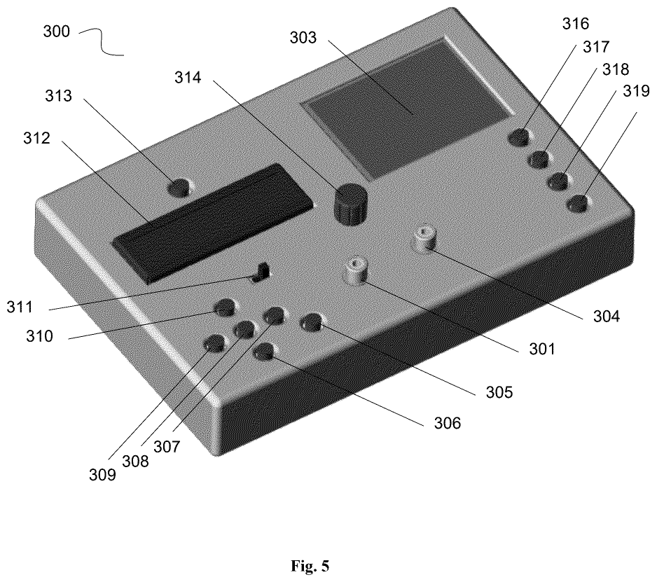

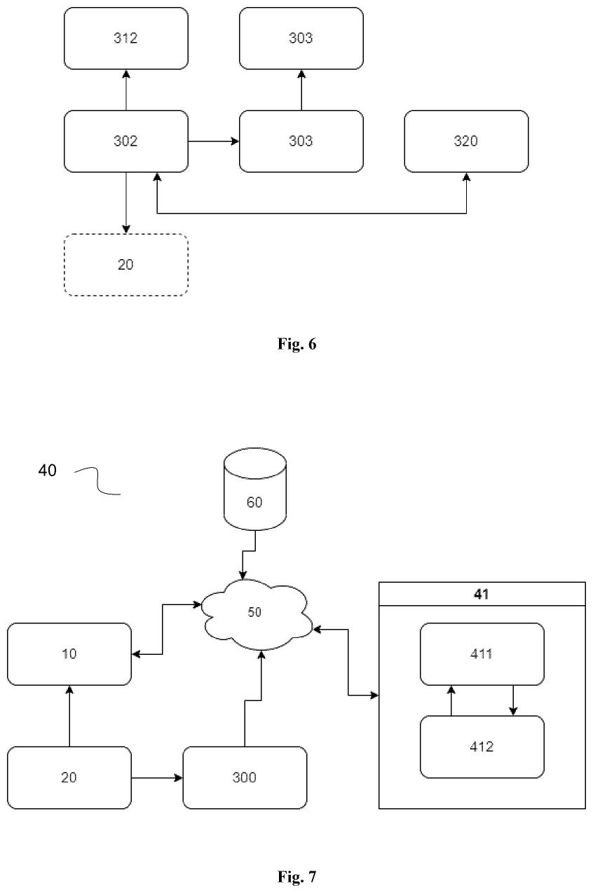

After the printed circuit board 20 has been checked, device 10 can measure the signals that pass through the soldered electronic components. In order to do this, for example, but not limited to, the output of the printed circuit board 20 may be coupled with the input 301 of device 300 for generating and/or measuring electrical signals. In addition, but not limited to, as shown in FIG. 5, there may be provided a device 300 for generating and/or measuring electric signals, the device comprising at least a signal generator unit 302 and an oscilloscope unit 302, and adapted to be coupled with a printed circuit board 20, wherein the signal generator unit 302 is adapted to send signals to an input of the oscilloscope unit 303 and an input of the printed circuit board 20 by means of the output 304 of device 300 with at least one electronic component soldered to it, and wherein the oscilloscope unit 303 has two channels and presents at least a signal that comes from the signal generator unit 302 directly and a signal that comes from the signal generator unit 302 via the printed circuit board 20. Furthermore, but not limited to, as the inventor unexpectedly discovered, not every device that is similar to device 300 may be suitable for use by an untrained user, for example, a child, who lacks specialized knowledge of how to operate complex generator/oscilloscope devices. Therefore, preferably, but not limited to, there may be provided device 30, which is equipped with only the following input devices: a latching button 313 for turning device 30 on and off; a latching button 305 for selecting either DC signal or AC signal; a non-latching button 306 for decreasing the signal frequency, when device 30 operates in its signal frequency setting mode, and changing the signal type when interacting with a graphical user interface, when device 30 operates in its signal type selection mode; a non-latching button 310 for increasing the signal frequency, when device 30 operates in its signal frequency setting mode, and changing the signal type when interacting with a graphical user interface, when device 30 operates in its signal type selection mode; a non-latching button 307 for selecting voltage, when device 30 operates in its signal frequency adjustment mode; a non-latching button 309 for selecting voltage, when device 30 operates in its signal frequency adjustment mode; a non-latching button 308 for switching generation of a selected signal on and off; a wheel (variable resistor, potentiometer) 314 for adjusting the generator output signal's amplitude; a switch 311 for switching between a low-frequency signal and high-frequency signal; non-latching buttons 316, 317 for input when interacting with a graphical user interface, when device 30 operates in its signal sampling mode or in its real-time signal mode; a non-latching button 318 for initiating interaction with a graphical user interface and for input when interacting with the graphical user interface, when device 30 operates in its real-time signal mode; a non-latching button 319 for initiating and breaking signal sampling mode of device 30, for input when interacting with a graphical user interface, when device 30 operates in its real-time signal mode, for switching between channels; and with only the following output devices: a display 312 for presenting information on the type and/or frequency of an output signal 304 and/or the state of a generator unit 302, and for presenting the varying voltage, when device 30 operates in its setup mode; a display 303 for presenting oscilloscope trace and a graphical user interface to interact with it.

In addition, alternatively, but not limited to, printed circuit board 20 or a similar one can be substituted by a protoboard (not shown in the drawing), which is, preferably, but not limited to, not a printed circuit board 20 or a similar one, or any other printed circuit board. Such a protoboard, preferably, but not limited to, is adapted to be detachably coupled to at least one electronic component, in which case the signal generator unit 302 is adapted to send signals to an input of the oscilloscope unit 303 and an input of the protoboard with an electronic component coupled to it; wherein the oscilloscope unit 303 has two channels and presents at least a signal that comes from the signal generator unit 302 directly and a signal that comes from the signal generator unit 302 via the protoboard.

Therefore, there may be provided a method for measuring signals, wherein at least one electronic component is placed on a protoboard, the protoboard is coupled to a disclosed device 300 for generating and/or measuring electrical signals, a signal is sent to the protoboard's input by means of signal generator unit 302 of the device 300, and a signal value is obtained by means of oscilloscope unit 303 of the device 300.

Therefore, there may be provided a kit for generating and/or measuring electrical signals comprising at least one or more of the disclosed devices 300 for generating and/or measuring electrical signals; one or more protoboards adapted to couple to any of the devices 300 for generating and/or measuring electrical signals; and one or more electronic components adapted to be detachably coupled with a protoboard.

In addition, preferably, but not limited to, as shown in FIG. 7, there may be provided a system 40 for monitoring soldered connections on a printed circuit board, the system comprising at least one or more of the disclosed devices 10 for monitoring soldered connections on a printed circuit board, wherein each of the devices is adapted to store in its memory results of said check and is equipped with a transceiver 16 adapted to transmit said stored results via a data exchange network 50; and a server 41 that comprises at least one or more processors 411 and a memory 412 that stores at least a program code, which, when executed by the processor 411, prompts it to at least receive and store in the server 41 memory 412 said results of a check transmitted by any one of the monitoring devices 10. In addition, preferably, but not limited to, the check result and/or user instructions mentioned above can be received by automated workplace 42 of the monitoring user from server 41 via data exchange network 50. In addition, for example, but not limited to, server's memory 412 may store a program code, which, when executed by processor 411 of server 41, prompts it to perform steps of a method that consists in analyzing the received results of the check and generating user instructions, which, for example, but not limited to, may subsequently be sent via data exchange network 50 to a corresponding device 10 to be presented to the user that undergoes training by means of the device's output device. In addition, but not limited to, system 40 may also include one or more of the disclosed devices 300 coupled with disclosed printed circuit boards 20 or disclosed protoboards, wherein, therefore, devices 300 may be equipped with transceivers 320 that are used for data exchange with the system's server 40 via network 50, the system 40 being, therefore, a system for monitoring soldered connections on a printed circuit board and/or analyzing electrical signals. For example, but not limited to, in this way, at least one set of instructions for signal generator unit 302 can be generated by means of server 41, wherein the instructions may be generated based on the results of the check.

Thus, preferably, but not limited to, according to the present disclosure, there may be provided a computer device. Most typically, said computer device comprises at least one or more processors, and a memory that stores a corresponding program code as disclosed above. At the same time, said computer device can act as a corresponding server of a corresponding system that, therefore, also comprises at least one or more processors and a memory, which are, therefore, essentially identical to the processor(s) and the memory of the computer devices disclosed above, respectively. For example, but not limited to, the memory (computer-readable medium) may comprise a non-volatile memory (NVRAM); a random-access memory (RAM); a read-only memory (ROM); an electrically erasable programmable read-only memory (EEPROM); a flash drive or other memory technologies; a CD-ROM, a digital versatile disk (DVD) or other optical/holographic media; magnetic tapes, magnetic film, a hard disk drive or any other magnetic drive; and any other medium capable of storing and encoding the necessary information. In addition, but not limited to, the memory comprises a computer-readable medium based on the computer memory, either volatile or non-volatile, or a combination thereof. In addition, but not limited to, exemplary hardware devices include solid-state drives, hard disk drives, optical disk drives, etc. For instance, but not limited to, the computer-readable medium (memory) is not a temporary memory (i.e. a permanent, non-transitive memory), and therefore it does not contain a temporary (transitive) signal. In addition, but not limited to, the memory may store an approximate environment in which, using computer commands or codes, including those stored in the server's memory, any of the previously disclosed computer procedures, executed by the processor of the computer device, can be performed. In addition, but not limited to, the computer device, if it is not a thin client, contains one or more processors that are designed to execute computed commands or codes that are stored in the device's memory in order to perform the disclosed procedures. In addition, but not limited to, the server, essentially, can be similar to the computer device, if it is not a thin client, and, therefore, contain one or more processors that are designed to execute computed commands or codes that are stored in the server's memory in order to perform the disclosed procedures. In addition, but not limited to, any system disclosed herein may further comprise a database 60. Said database may be, but not limited to, a hierarchical database, a network database, a relational database, an object database, an object-oriented database, an object-relational database, a spatial database, a combination of two or more said databases, etc. In addition, but not limited to, the database at least stores data, parameters, raw data, marked-up data, modified data, machine learning models, and other information in its memory or a suitable memory of another computer device that is connected to any of the disclosed computer devices and/or the server, which may be, but not limited to, a memory that is similar to any of the disclosed memories, and which can be accessed via the server. In addition, but not limited to, there is provided a server, which, in addition to the functions mentioned above, stores and facilitates the execution of computer-readable commands and codes disclosed herein, which, accordingly, won't be described again. In addition, but not limited to, the server, in addition to the functions mentioned above, is capable of controlling the data exchange in the system. In addition, but not limited to, data exchange within the disclosed system is performed with the help of one or more data exchange networks 50. In addition, but not limited to, data exchange networks 50 may include, but not limited to, one or more local area networks (LAN) and/or wide area networks (WAN), or may be represented by the Internet or Intranet, or a virtual private network (VPN), or a combination thereof, etc. In addition, but not limited to, the server is further capable of providing a virtual computer environment for the components of the system to interact with each other. In addition, but not limited to, network 50 is used to ensure interaction between the computer device, the server, optionally, the database, and, optionally, the systems mentioned above and other systems. In addition, but not limited to, the non-thin client computer device and/or server may be connected to database 60 directly, using wired or wireless communication methods, which are known in the art and therefore are not described in further detail, or, but not limited to, the database may be implemented in the memory of any computer device, including the server. In addition, but not limited to, a suitable non-thin client computer device can act as a system server for other computer devices, which are thin clients. In addition, but not limited to, most typically, the components of the computer devices disclosed herein and the server components are interconnected, including though some kind of data bus.

The present disclosure of the claimed invention demonstrates only certain exemplary embodiments of the invention, which by no means limit the scope of the claimed invention, meaning that it may be embodied in alternative forms that do not go beyond the scope of the present disclosure and which may be obvious to persons having ordinary skill in the art.

1. A device for controlling soldered connections on a printed circuit board, the device comprising at least a housing with a seat for a printed circuit board to be controlled, wherein the seat is equipped with a plurality of spring-loaded contacts adapted to couple to counter contacts on the back of said printed circuit board; the device is also equipped with at least one processor that is coupled to said contacts, so that it is possible to check soldered connections on a controlled printed circuit board for at least one of the following defects: solder skip, short circuit, wrong electronic component rating, wrong electronic component, wrong placement of an electronic component; and with a memory storing a program code, which, when executed by the processor, prompts it to at least check at least one soldered connection with at least one electronic component on a printed circuit board placed on the seat for at least one of the defects.

2. The device of claim 1, characterized in that said memory is further adapted to store the results of a check.

3. The device of claim 2, characterized in that it is additionally equipped with a transceiver adapted to transmit stored results to a server of a system for controlling soldered connections on a printed circuit board, wherein said memory additionally contains at least a program code, which, when executed by the processor, prompts it to send stored results to the server.

4. The device of claim 1, characterized in that it is additionally equipped with an output device adapted to at least present the results of a check.

5. The device of claim 4, characterized in that said memory additionally contains at least a program code, which, when at least one of the defects mentioned above is detected, is executed by the processor, prompting it to generate instructions for a user on how to eliminate the detected defect.

6. The device of claim 5, characterized in that said output device is adapted to present generated instructions to a user.
